(19) United States
(12) Patent Application Publication
(10) Pub. No.: US 2026/0303055 A1
(43) Pub. Date: Oct. 1, 2026

(54) ACOUSTIC WAVE DEVICE AND FILTER DEVICE

(71) Applicant: Murata Manufacturing Co., Ltd., Nagaokakyo-shi (JP)

(72) Inventor: Sena SUZUKI, Nagaokakyo-shi (JP)

(21) Appl. No.: 19/633,000

(22) Filed: Mar. 30, 2026

(30) Foreign Application Priority Data
Mar. 31, 2025 (JP) 2025-058123

(51) Int. Cl. H03H 9/02; H03H 9/17; H03H 9/56

(52) U.S. Cl. CPC H03H 9/02086; H03H 9/02157; H03H 9/02228; H03H 9/175; H03H 9/568

(57) ABSTRACT

An acoustic wave device includes a piezoelectric layer including a first main surface and a second main surface that face away from each other, a first electrode on the first main surface of the piezoelectric layer, and a second electrode on the second main surface of the piezoelectric layer, that faces the first electrode with the piezoelectric layer therebetween. The piezoelectric layer includes a first region and a second region in which a polarization direction is reversed from a polarization direction in the first region. The first region and the second region are cyclically arranged in a direction orthogonal to a thickness direction of the piezoelectric layer. The acoustic wave device further includes mass-addition films provided on the first electrode and cyclically positioned in a direction in which the first region and the second region are arranged.

### CROSS REFERENCE TO RELATED APPLICATIONS

This application claims the benefit of priority to Japanese Patent Application No. 2025-058123 filed on Mar. 31, 2025. The entire contents of this application are hereby incorporated herein by reference.

### BACKGROUND OF THE INVENTION

### 1. Field of the Invention

The present invention relates to acoustic wave device and a filter devices.

### 2. Description of the Related Art

Conventionally, acoustic wave devices are widely used as filters of mobile phones. Japanese Unexamined Patent Application Publication No. 2012-165032 discloses an example of acoustic wave devices. In such an acoustic wave device, a piezoelectric body has a cyclic polarization reversal structure. Electrodes are provided on both main surfaces of the piezoelectric body. Both electrodes face each other with a piezoelectric body therebetween. An acoustic wave is excited by an alternating electric field being applied through both electrodes.

### SUMMARY OF THE INVENTION

However, in the acoustic wave device described in Japanese Unexamined Patent Application Publication No. 2012-165032, the reflection coefficient is not sufficiently large. Accordingly, the acoustic wave device has difficulty in sufficiently suppressing the leakage of an acoustic wave. Accordingly, there is concern that the acoustic wave device described above cannot sufficiently maintain good electrical characteristics.

Example embodiments of the present invention provide acoustic wave devices and filter devices that each effectively confine an acoustic wave in a region in which the acoustic wave is excited.

According to an example embodiment of the present invention, an acoustic wave device includes a piezoelectric layer including a first main surface and a second main surface that face away from each other, a first electrode provided on the first main surface of the piezoelectric layer, and a second electrode provided on the second main surface of the piezoelectric layer that faces the first electrode with the piezoelectric layer therebetween, in which the piezoelectric layer includes a first region and a second region in which a polarization direction is reversed from a polarization direction in the first region, and the first region and the second region are cyclically arranged in a direction orthogonal to a thickness direction of the piezoelectric layer, the acoustic wave device further including a plurality of mass-addition films provided on the first electrode and cyclically positioned in a direction in which the first region and the second region are arranged.

According to an example embodiment of the present invention, a filter device includes a plurality of resonators, in which two or more of the plurality of resonators are each defined by the acoustic wave device according to another example embodiment of the present invention, and the acoustic wave device defining one of the two or more of the plurality of resonators has a center-to-center distance between the first region and the second region adjacent to each other that differs from a center-to-center distance of the acoustic wave device defining another one of the two or more of the plurality of resonators.

Acoustic wave devices and filter devices according to example embodiments of the present invention each effectively confine an acoustic wave in a region in which the acoustic wave is excited.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic elevational cross-sectional view of an acoustic wave device according to a first modification of the first example embodiment of the present invention.

FIG. 4 is a schematic elevational cross-sectional view of an acoustic wave device according to a second modification of the first example embodiment of the present invention.

FIG. 5 is a schematic elevational cross-sectional view of an acoustic wave device according to a third modification of the first example embodiment of the present invention.

FIG. 6 is a schematic plan view of an acoustic wave device according to a second example embodiment of the present invention.

FIG. 7 is a schematic plan view of an acoustic wave device according to a first modification of the second example embodiment of the present invention.

FIG. 8 is a schematic plan view of an acoustic wave device according to a second modification of the second example embodiment of the present invention.

FIG. 9 is a schematic plan view of an acoustic wave device according to a third example embodiment of the present invention.

FIG. 10 is a schematic plan view of an acoustic wave device according to a fourth example embodiment of the present invention.

FIG. 11 is a schematic plan view of an acoustic wave device according to a fifth example embodiment of the present invention.

FIG. 12 is a schematic elevational cross-sectional view of an acoustic wave device according to a sixth example embodiment of the present invention.

FIG. 13 is a schematic elevational cross-sectional view of an acoustic wave device according to a seventh example embodiment of the present invention.

FIG. 14 is a circuit diagram of a filter device according to an eighth example embodiment of the present invention.

### DETAILED DESCRIPTION OF THE EXAMPLE EMBODIMENTS

The present invention will be clarified below by describing specific example embodiments of the present invention with reference to the drawings.

It should be noted that the example embodiments described in this specification are exemplary and that partial substitutions or combinations of structures between different example embodiments are possible.

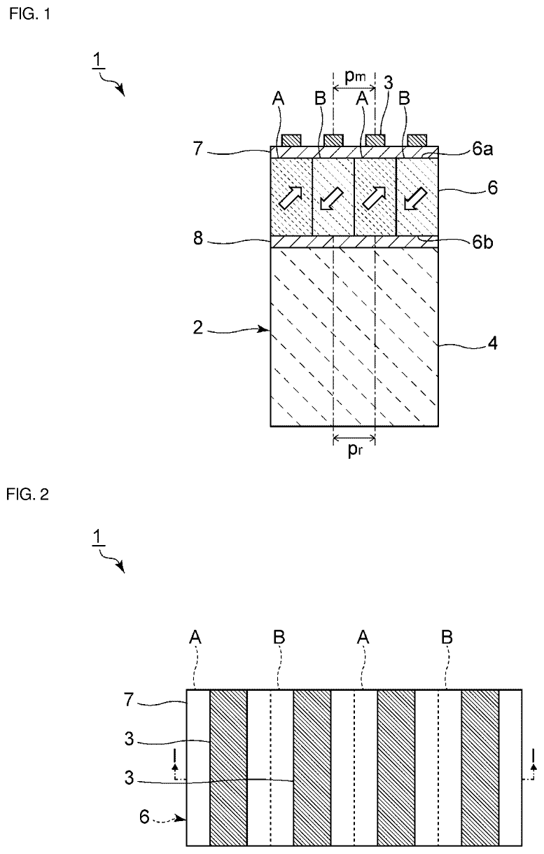

FIG. 1 is a schematic elevational cross-sectional view of an acoustic wave device according to a first example embodiment of the present invention. FIG. 2 is a schematic plan view of the acoustic wave device according to the first example embodiment of the present invention. It should be noted that FIG. 1 is a schematic cross-sectional view taken along line I-I in FIG. 2. In FIG. 2, mass-addition films, which will be described later, are hatched. This is the same in the schematic plan views other than FIG. 2.

As illustrated in FIG. 1, an acoustic wave device 1 includes a piezoelectric substrate 2. The piezoelectric substrate 2 is a substrate that has piezoelectricity. In the present example embodiment, the piezoelectric substrate 2 is a multilayer substrate that includes a piezoelectric layer 6 made of a piezoelectric material. More specifically, the piezoelectric substrate 2 includes a support substrate 4 and the piezoelectric layer 6 described above. The piezoelectric layer 6 is provided on the support substrate 4. It should be noted that the multilayer structure of the piezoelectric substrate 2 is not limited to the structure described above. The piezoelectric substrate 2 only needs to include at least the piezoelectric layer 6. For example, an intermediate layer may also be provided between the support substrate 4 and the piezoelectric layer 6. Alternatively, the piezoelectric substrate 2 may include only the piezoelectric layer 6.

The piezoelectric layer 6 includes a first main surface 6a and a second main surface 6b. The first main surface 6a and the second main surface 6b face away from each other. Of the first main surface 6a and the second main surface 6b, the second main surface 6b is the main surface close to the support substrate 4.

The piezoelectric layer 6 includes a plurality of first regions A and a plurality of second regions B. The arrows in the first regions A and the second region B in FIG. 1 indicate the polarization directions in the first regions A and the second regions B. The first regions A and the second regions B have a relationship in which the polarization directions thereof are reversed from each other. The relationship in which the polarization directions in two portions are reversed from each other indicates that the acoustic characteristics of crystals are the same and only the polarization directions differ from each other by approximately 180° between these portions. The difference in the polarization directions between the first regions A and the second regions B can be evaluated by using, for example, a scanning nonlinear dielectric microscopy (SNDM).

It should be noted that, when the acoustic characteristics of the crystals are the same, the crystal structures are substantially the same. Whether the crystal structures are the same can be determined, for example, by checking the crystal structures with X-ray diffraction (XRD) or by checking the state of polarization with a scanning nonlinear dielectric microscopy.

When the polarization directions in two portions are completely reversed from each other, the absolute value of the difference in θ of the Euler angles (φ, θ, ψ) of the two portions is about 180°, for example. However, when the polarization directions in two portions are reversed from each other in this specification, the case in which the angle defined by both polarization axes falls within about 180°±5°, for example, is included.

The first regions A and the second regions B are cyclically arranged in a direction orthogonal to the thickness direction of the piezoelectric layer 6. More specifically, the first regions A and the second regions B are alternately arranged in one direction orthogonal to the thickness direction of the piezoelectric layer 6. It should be noted that, in the piezoelectric layer 6, the first regions A and the second regions B extend from the first main surface 6a to the second main surface 6b. Accordingly, the boundaries between the first regions A and the second regions B also extend to the first main surface 6a and the second main surface 6b. The direction in which the first regions A and the second regions B are arranged is referred to below as a first direction. The direction orthogonal to the first direction and the thickness direction of the piezoelectric layer 6 is referred to as a second direction. The region in which the first regions A and the second regions B are cyclically positioned is referred to as a cyclic polarization reversal region.

As illustrated in FIG. 2, in the present example embodiment, the whole of the piezoelectric layer 6 is the cyclic polarization reversal region. Specifically, throughout the piezoelectric layer 6 in the first direction, the first regions A and the second regions B are arranged alternately. The first regions A and the second regions B extend from one edge portion to the other edge portion of the piezoelectric layer 6 in the second direction. Accordingly, the boundaries between the first regions A and the second regions B also extend from the one edge portion described above to the other edge portion.

However, for example, when the acoustic wave device 1 is used in a filter device, the acoustic wave device 1 and other resonators may share the same piezoelectric layer. In addition, the piezoelectric layer 6 illustrated in FIG. 2 may be a portion of a larger piezoelectric layer. In this case, for example, the cyclic polarization reversal region may be surrounded by the first regions A or may be surrounded by the second regions B. Alternatively, the cyclic polarization reversal region may be surrounded by regions with a different polarization direction from the first regions A or the second regions B.

Returning to FIG. 1, a first electrode 7 is provided on the first main surface 6a of the piezoelectric layer 6. A second electrode 8 is provided on the second main surface 6b of the piezoelectric layer 6. Each of the first electrode 7 and the second electrode 8 has a flat plate shape. The first electrode 7 and the second electrode 8 face each other with the piezoelectric layer 6 therebetween. More specifically, the first electrode 7 and the second electrode 8 face each other with the cyclic polarization reversal region of the piezoelectric layer 6 therebetween. In the present example embodiment, the second electrode 8 is located in at least a portion between the support substrate 4 and the piezoelectric layer 6. The second electrode 8 may be embedded in the support substrate 4.

In the acoustic wave device 1, the first electrode 7 is connected to a signal potential. On the one hand, the second electrode 8 is connected to a reference potential. However, the present invention is not limited to this example.

A plurality of mass-addition films 3 are provided on the first electrode 7. The plurality of mass-addition films 3 are cyclically positioned in the first direction. Specifically, in the present example embodiment, each of the mass-addition films 3 overlaps one of the first regions A or one of the second regions B in plan view. The mass-addition films 3 have a rod-like shape extending in the second direction in plan view.

Plan view in this specification refers to view of the acoustic wave device in a direction corresponding to the upside in FIG. 1. In FIG. 1, for example, the upside is the side close to the piezoelectric layer 6 of the side close to the support substrate 4 and the side close to the piezoelectric layer 6. In addition, in this specification, plan view is the same as view in a main surface facing direction. The main surface facing direction is the direction in which the first main surface 6a and the second main surface 6b of the piezoelectric layer 6 face away from each other. More specifically, the main surface facing direction is, for example, the normal direction of the first main surface 6a. The main surface facing direction is the same as the thickness direction of the piezoelectric layer 6.

The present example embodiment preferably includes the structures described below. (1) The first electrode 7 is provided on the first main surface 6a of the piezoelectric layer 6, and the second electrode 8 is provided on the second main surface 6b of the piezoelectric layer 6. (2) The first regions A and the second regions B are cyclically arranged in the first direction in the piezoelectric layer 6. 3) The plurality of mass-addition films 3 are cyclically positioned in the first direction on the first electrode 7. As a result, an acoustic wave can be effectively confined in the region in which the acoustic wave is excited. This will be described below.

The structures (1) and (2) described above excite an acoustic wave in a plate wave mode. More specifically, when an alternating electric field is applied to the piezoelectric layer 6 from the first electrode 7 and the second electrode 8, the first regions A and the second regions B are displaced in directions opposite to each other. As a result, an acoustic wave in the plate wave mode is excited in the cyclic polarization reversal region. The direction parallel to the first direction is an acoustic wave propagation direction.

The structure (3) described above can add mass to the first regions A or the second regions B. As a result, an acoustic wave can be reflected in the acoustic wave propagation direction. In other words, a reflection coefficient can be obtained as a parameter of the acoustic wave device 1. As described above, for example, when the acoustic wave device 1 is used in a filter device, the piezoelectric layer may include the outer portion of the piezoelectric layer 6 illustrated in FIG. 2. Also in such a case, in the present example embodiment, an acoustic wave can be reflected in the cyclic polarization reversal region. Accordingly, an acoustic wave can be effectively confined in the region in which the acoustic wave is excited.

When the center-to-center distance in the first direction between the first region A and the second region B that are adjacent to each other is pᵣ and the center-to-center distance in the first direction between the mass-addition films 3 adjacent to each other is pₘ as illustrated in FIG. 1, pₘ=pᵣ holds in the example embodiment. As a result, an acoustic wave can be efficiently confined by a Bragg reflection in the region in which the acoustic wave is excited.

It should be noted that pₘ≠pᵣ is allowed. However, when n is a natural number equal to or greater than 1, pₘ=npᵣ is preferable. Also in this case, an acoustic wave can be efficiently confined by a Bragg reflection in the region in which the acoustic wave is excited.

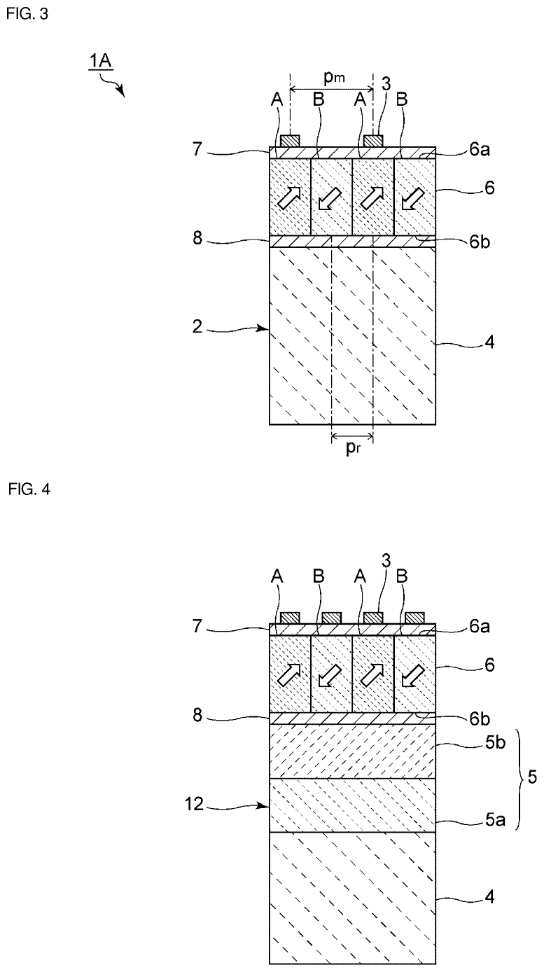

For example, in the first modification of the first example embodiment illustrated in FIG. 3, pₘ=2pᵣ holds. Specifically, in an acoustic wave device 1A, each of the mass-addition films 3 overlaps one of the first regions A in plan view. On the one hand, each of the mass-addition films 3 overlaps none of the second regions B in plan view. As described above, each of the mass-addition films 3 does not need to overlap portions of the first regions A or the second regions B in plan view. In such a case, the plurality of mass-addition films 3 only need to be cyclically positioned in the first direction. As a result, an acoustic wave can be confined in a region in which the acoustic wave is excited.

In addition, in the modification, pₘ=npᵣ holds. Specifically, n=2 and pₘ=2pᵣ. As a result, an acoustic wave can be efficiently confined by a Bragg reflection in the region in which the acoustic wave is excited.

Examples of the materials for the structures of the acoustic wave device 1 illustrated in FIG. 1 will be described below. In this specification, a main component refers to a component that occupies more than about 50 wt % in each of the structures. The material of the main component described above may be present in any of the states: single crystal state, polycrystal state, amorphous state, or a state in which these are mixed.

The material of the support substrate 4 may be, for example, a piezoelectric body such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, or a semiconductor such as silicon, or a material including any of these materials as a main component. It should be noted that the spinel described above includes an aluminum compound that contains one or more elements selected from Mg, Fe, Zn, and Mn and oxygen. Examples of the spinel described above may be MgAl₂O₄, FeAl₂O₄, ZnAl₂O₄, and MnAl₂O₄. The material of the support substrate 4 is preferably silicon. In this case, the absolute value of the temperature coefficient of frequency (TCF) of the acoustic wave device 1 can be reduced. As a result, the frequency-temperature characteristics of the acoustic wave device 1 can be improved.

The material of the piezoelectric layer 6 may be, for example, lithium tantalate, lithium niobate, zinc oxide, or aluminum nitride. The material of the piezoelectric layer 6 is preferably lithium tantalate or lithium niobate. In this case, the resonance characteristics of the acoustic wave device 1 can be easily enhanced.

The material of the first electrode 7 and the second electrode 8 may be, for example, one or more metals including titanium, molybdenum, ruthenium, tungsten, aluminum, platinum, iridium, copper, chromium, or scandium. Each of the first electrode 7 and the second electrode 8 may include a single-layer metal film or a multilayer metal film.

The material of the mass-addition films 3 may be a dielectric such as silicon oxide, silicon nitride, silicon oxynitride, or tantalum oxide or one or more metals selected from the group consisting of titanium, molybdenum, ruthenium, tungsten, aluminum, platinum, iridium, copper, chromium, or scandium. The material of the mass-addition films 3 is preferably at least one of platinum and molybdenum. In this case, mass added to the piezoelectric layer 6 can be easily increased. As a result, an acoustic wave can be further confined in the region in which the acoustic wave is excited.

Each of the mass-addition films 3 may be a single-layer metal film or dielectric film or may be a multilayer metal film or dielectric film.

When a metal is used as the material of the mass-addition films 3, the mass-addition films 3 and the first electrode 7 may be configured integrally by the same material.

In the present example embodiment, the support substrate 4 is a high-acoustic-velocity layer. A high-acoustic-velocity layer is a relatively high acoustic-velocity layer. More specifically, the acoustic velocity of a bulk wave propagating through the high-acoustic-velocity layer is higher than the acoustic velocity of an acoustic wave propagating through the piezoelectric layer 6. In addition, in the piezoelectric substrate 2, the support substrate 4 and the piezoelectric layer 6 as the high-acoustic-velocity layers are laminated together. As a result, the energy of an acoustic wave can be effectively confined in the direction in which the support substrate 4 and the piezoelectric layer 6 are laminated together.

It should be noted that the multilayer structure of the piezoelectric substrate 2 is not limited to the structure described above. For example, in the second modification of the first example embodiment illustrated in FIG. 4, a piezoelectric substrate 12 includes the support substrate 4, the intermediate layer 5, and the piezoelectric layer 6. The intermediate layer 5 specifically includes a first layer 5a and a second layer 5b. The first layer 5a is provided on the support substrate 4. The second layer 5b is provided on the first layer 5a. The piezoelectric layer 6 is provided on the second layer 5b.

In the modification, the first layer 5a of the intermediate layer 5 is a high-acoustic-velocity layer. The first layer 5a may be made of the same material as the support substrate 4 described above.

The second layer 5b of the intermediate layer 5 is a low-acoustic-velocity layer. A low-acoustic-velocity is a relatively low acoustic-velocity layer. More specifically, the acoustic velocity of a bulk wave propagating through the low-acoustic-velocity layer is lower than the acoustic velocity of a bulk wave propagating through the piezoelectric layer 6. The material of the second layer 5b, which is a low-acoustic-velocity layer, may be, for example, a dielectric such as glass, silicon oxide, silicon oxynitride, lithium oxide, tantalum oxide, a compound obtained by adding fluorine, carbon, or boron to silicon oxide, or a material including any of these materials as a main component.

The intermediate layer 5 in the modification is a multilayer film. However, the intermediate layer 5 may be, for example, a single-layer dielectric film.

In the piezoelectric substrate 12, the first layer 5a, which is a high-acoustic-velocity layer, the second layer 5b, which is a low-acoustic-velocity layer, and the piezoelectric layer 6 are laminated together in this order. As a result, the energy of an acoustic wave can be effectively confined in the direction in which the support substrate 4, the intermediate layer 5, and the piezoelectric layer 6 are laminated. In addition, as in the first example embodiment, an acoustic wave can be effectively confined also in the acoustic wave propagation direction in the region in which the acoustic wave is excited. The piezoelectric substrate 12 is also applicable to the structures of example embodiments of the present invention excluding the modification.

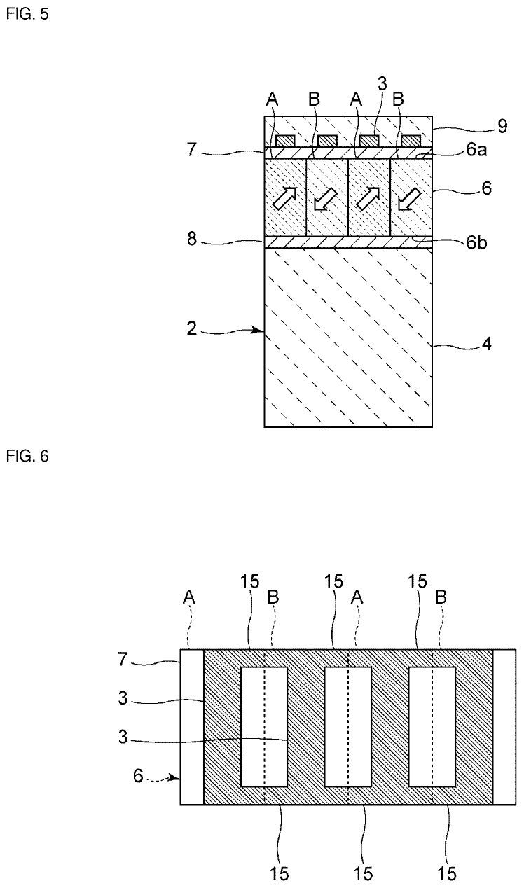

In an example embodiment of the present invention, the mass-addition films 3 may be covered with a dielectric film. For example, in the third modification of the first example embodiment illustrated in FIG. 5, a dielectric film 9 is provided on the first electrode 7 so as to cover the mass-addition films 3. When a dielectric is used as the material of the mass-addition films 3, a material different from that of the mass-addition films 3 is used as the material of the dielectric film 9. The material of the dielectric film 9 may be, for example, silicon oxide, silicon nitride, or silicon oxynitride.

In the modification, the thickness of the dielectric film 9 is greater than the thickness of the mass-addition film 3. Accordingly, the mass-addition films 3 are embedded in the dielectric film 9. It should be noted that the thickness of the dielectric film 9 may be smaller than the thickness of the mass-addition film 3.

Since the dielectric film 9 is provided, the first electrode 7 and the mass-addition films 3 are less likely to be broken. In addition, as in the first example embodiment, an acoustic wave can be effectively confined in the region in which the acoustic wave is excited. The structure in which the dielectric film 9 is provided is also applicable to the structure of the present invention excluding the modification.

FIG. 6 is a schematic plan view of an acoustic wave device according to a second example embodiment. In FIG. 6, the mass-addition films 3 and connectors, which will be described later, are hatched. This is also the same in the schematic plan views other than FIG. 6.

The present example embodiment differs from the first example embodiment in that the plurality of connectors 15 are provided on the first electrode 7. The plurality of connectors 15 are connected to the plurality of mass-addition films 3, respectively. The acoustic wave device according to the present example embodiment has the same structure as the acoustic wave device 1 according to the first example embodiment with the exception of the points described above.

In the present example embodiment, the connectors 15 are provided between the adjacent mass-addition films 3 and connect the adjacent mass-addition films 3 to each other. More specifically, some connectors 15 of all the connectors 15 connect, to each other, one ends in the second direction of the adjacent mass-addition films 3. The remaining connectors 15 connect, to each other, the other ends in the second direction of the adjacent mass-addition films 3. The one ends and the other ends in the second direction of the mass-addition films 3 may be simply referred to below as the one ends and the other ends.

The material of the connectors 15 may be, for example, a dielectric such as silicon oxide, silicon nitride, silicon oxynitride, or tantalum oxide or one or more metals selected from the group consisting of titanium, molybdenum, ruthenium, tungsten, aluminum, platinum, iridium, copper, chromium, or scandium.

In the present example embodiment, the plurality of connectors 15 are configured integrally by the same material as the plurality of mass-addition films 3. The thickness of the plurality of connectors 15 and the thickness of the plurality of mass-addition films 3 are the same as each other. The plurality of connectors 15 and the plurality of mass-addition films 3 are not laminated together.

It should be noted that the plurality of connectors 15 and the plurality of mass-addition films 3 may be made of different materials.

The material of the plurality of connectors 15 and the material of the plurality of mass-addition films 3 are preferably metals. In this case, the plurality of mass-addition films 3 are electrically connected to each other not only by the first electrode 7 but also by the plurality of connectors 15. As a result, the power durability can be effectively enhanced.

In the present example embodiment, the piezoelectric layer 6, the first electrode 7, and the second electrode 8 are configured similarly to those in the first example embodiment, and the plurality of mass-addition films 3 are cyclically positioned in the first direction on the first electrode 7. Accordingly, also in the present example embodiment, an acoustic wave can be effectively confined in the region in which the acoustic wave is excited.

It should be noted that the structure of the connectors 15 is not limited to the structure described above. A first modification and a second modification of the second example embodiment, which differ from the second example embodiment only in the structure of the connectors 15, will be described below. Also in the first modification and the second modification, as in the second example embodiment, an acoustic wave can be effectively confined in the region in which the acoustic wave is excited.

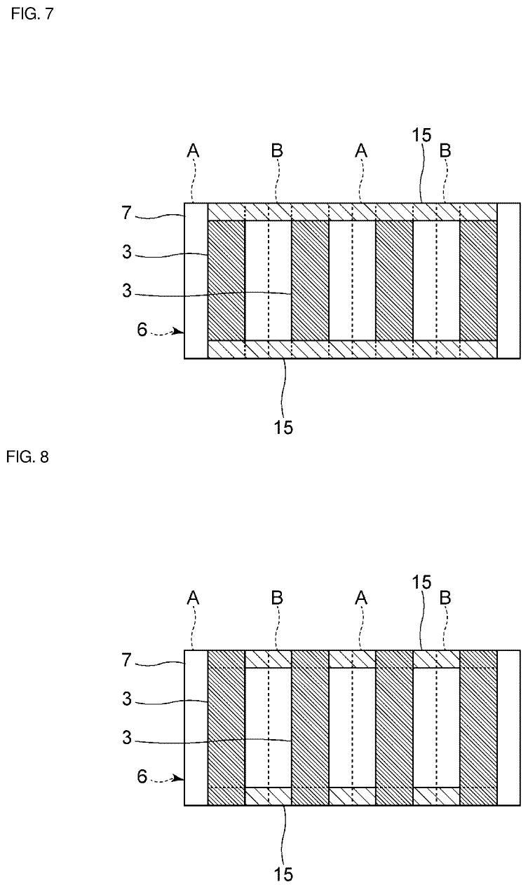

In the first modification illustrated in FIG. 7, one band-shaped connector 15 is continuously provided over the plurality of mass-addition films 3 and the first electrode 7 so as to connect one ends of the plurality of mass-addition films 3 to each other. Another band-shaped connector 15 is continuously provided over the plurality of mass-addition films 3 and the first electrode 7 so as to connect the other ends of the plurality of mass-addition films 3. In the modification, each of the connectors 15 has a portion that is not laminated with the mass-addition film 3 and a portion that is laminated with the mass-addition film 3. In the portion of the connector 15 that is laminated with the mass-addition film 3, the first electrode 7, the mass-addition film 3, and the connector 15 are laminated together in this order.

In the second modification illustrated in FIG. 8, each of the mass-addition films 3 is provided over the pair of connectors 15 and the first electrode 7. In the portion of the connector 15 that is laminated with the mass-addition film 3, the first electrode 7, the connector 15, and the mass-addition film 3 are laminated together in this order.

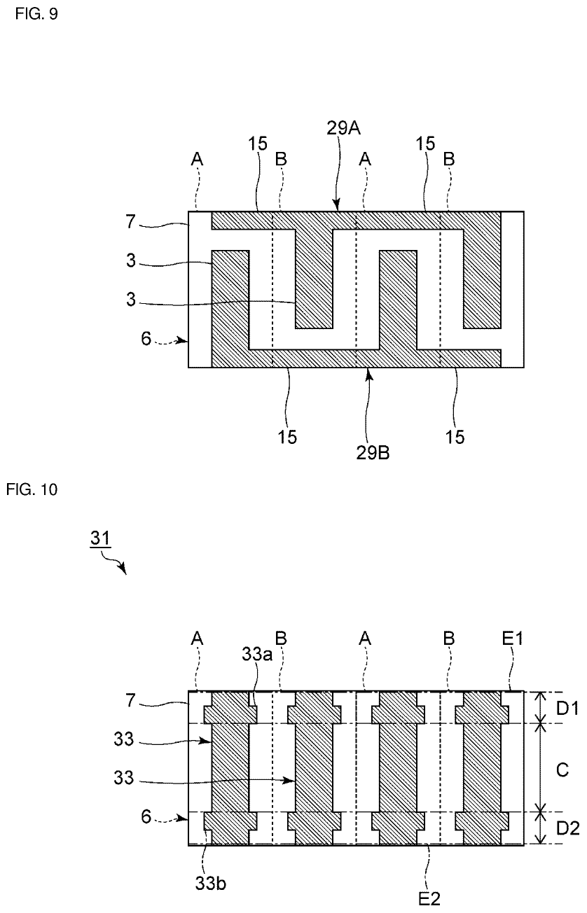

FIG. 9 is a schematic plan view of an acoustic wave device according to a third example embodiment.

The present example embodiment differs from the first example embodiment in that the plurality of connectors 15 are provided on the first electrode 7 and that a pair of comb-shaped structures is configured by the plurality of connectors 15 and the plurality of mass-addition films 3. The pair of comb-shaped structures are specifically a first comb-shaped structure 29A and a second comb-shaped structure 29B. The acoustic wave device according to the present example embodiment has the same structure as the acoustic wave device 1 according to the first example embodiment with the exception of the points described above.

Some connectors 15 of all the connectors 15 and some mass-addition films 3 of all the mass-addition films 3 constitute the first comb-shaped structure 29A. The remaining connectors 15 and the remaining mass-addition films 3 define the second comb-shaped structure 29B.

The first comb-shaped structure 29A includes alternate mass-addition films 3 of the plurality of mass-addition films 3 that are arranged in the first direction. Specifically, in the present example embodiment, all the mass-addition films 3 included in the first comb-shaped structure 29A overlap the second regions B in plan view. The one ends of these mass-addition films 3 are connected to each other by the plurality of connectors 15 included in the first comb-shaped structure 29A.

The mass-addition films 3 located between the plurality of mass-addition films 3 included in the first comb-shaped structure 29A are included in the second comb-shaped structure 29B. Specifically, in the present example embodiment, all the mass-addition films 3 included in the second comb-shaped structure 29B overlap the first regions A in plan view. The one ends of these mass-addition films 3 are connected to each other by the plurality of connectors 15 included in the second comb-shaped structure 29B.

The connectors 15 included in the first comb-shaped structure 29A face one ends of the mass-addition films 3 included in the second comb-shaped structure 29B with a gap therebetween. The connectors 15 included in the second comb-shaped structure 29B face one ends of the mass-addition films 3 included in the first comb-shaped structure 29A with a gap therebetween. The first comb-shaped structure 29A and the second comb-shaped structure 29B are interdigitated with each other.

In the first comb-shaped structure 29A in the present example embodiment, the connector 15 located at one end in the first direction of the plurality of connectors 15 is connected to only one mass-addition film 3. The other connector 15 included in the first comb-shaped structure 29A is connected to two mass-addition films 3. Similarly, in the second comb-shaped structure 29B, the connector 15 located at one end in the first direction of the plurality of connectors 15 is connected to only one mass-addition film 3. The other connector 15 included in the second comb-shaped structure 29B is connected to two mass-addition films 3. However, in the first comb-shaped structure 29A, each of the connectors 15 may be connected to two mass-addition films 3. This is the same for the second comb-shaped structure 29B.

In the present example embodiment, the piezoelectric layer 6, the first electrode 7, and the second electrode 8 are configured similarly to those in the first example embodiment, and the plurality of mass-addition films 3 are cyclically positioned in the first direction on the first electrode 7. Accordingly, also in the present example embodiment, an acoustic wave can be effectively confined in the region in which the acoustic wave is excited.

It should be noted that the first comb-shaped structure 29A may include only one connector 15. In this case, one band-shaped connector 15 may be provided so as to connect, to each other, the one ends of alternate mass-addition films 3 of the plurality of mass-addition films 3 that are arranged in the first direction. For example, the band-shaped connector 15 described above may be continuously provided over the plurality of mass-addition films 3 and the first electrode 7. Alternatively, the plurality of mass-addition films 3 may be provided over the band-shaped connector 15 described above and the first electrode 7. In addition, the band-shaped connector 15 described above only needs to face one ends of the plurality of mass-addition films 3 included in the second comb-shaped structure 29B with a gap therebetween.

Similarly, the second comb-shaped structure 29B may include only one connector 15. In this case, one band-shaped connector 15 may be provided so as to connect, to each other, the one ends of alternate mass-addition films 3 of the plurality of mass-addition films 3 that are arranged in the first direction. For example, the band-shaped connector 15 described above may be continuously provided over the plurality of mass-addition films 3 and the first electrode 7. Alternatively, the plurality of mass-addition films 3 may be provided over the band-shaped connector 15 described above and the first electrode 7. In addition, the band-shaped connector 15 described above only needs to face one ends of the plurality of mass-addition films 3 included in the first comb-shaped structure 29A with a gap therebetween. Also in these cases, as in the first example embodiment, an acoustic wave can be effectively confined in the region in which the acoustic wave is excited.

When the acoustic wave device includes at least one connector 15, the at least one connector 15 preferably connects at least two mass-addition films 3 to each other. As a result, when metals are used as the materials of the connector 15 and the plurality of mass-addition films 3, the power durability of the acoustic wave device can be enhanced.

FIG. 10 is a schematic plan view of an acoustic wave device according to a fourth example embodiment.

The present example embodiment differs from the first example embodiment in the structure of the plurality of mass-addition films 33. An acoustic wave device 31 according to the present example embodiment has the same structure as the acoustic wave device 1 according to the first example embodiment with the exception of the points described above.

The acoustic wave device 31 includes a central region C and a pair of outer side regions. The pair of outer side regions is, specifically, a first outer side region D1 and a second outer side region D2. The first outer side region D1 and the second outer side region D2 face each other with the central region C therebetween in the second direction.

More specifically, when a virtual line connecting, to each other, one ends in the second direction of the plurality of mass-addition films 33 is defined as a first envelope E1, the first outer side region D1 is a region from an edge portion of the central region C close to the first envelope E1 to the first envelope E1. When a virtual line connecting, to each other, the other ends in the second direction of the plurality of mass-addition films 33 is defined as a second envelope E2, the second outer side region D2 is a region from an edge portion of the central region C close to the second envelope E2 to the second envelope E2. It should be noted that the acoustic wave device according to the present invention excluding the present example embodiment also includes the central region C and the pair of outer side regions.

Each of the plurality of mass-addition films 33 has wide portions. The wide portions refer to portions of the mass-addition film 33 that are wider than the central region C. In the present example embodiment, the wide portions of each of the mass-addition films 33 are located in the first outer side region D1 and the second outer side region D2. Specifically, in each of the mass-addition films 33, a wide portion 33a is provided from a portion at edge portion of the central region C close to the first envelope E1 to a portion located between the edge portion and the first envelope E1. The wide portion 33a does not reach the first envelope E1.

On the other hand, in each of the mass-addition films 33, a wide portion 33b is provided from a portion at an edge portion of the central region C close to the second envelope E2 to a portion located between the edge portion and the second envelope E2. The wide portion 33b does not reach the second envelope E2.

The acoustic velocity in a region in which the wide portions 33a of the plurality of mass-addition films 33 are arranged is smaller than the acoustic velocity in the central region C. Similarly, the acoustic velocity in the region in which the wide portions 33b of the plurality of mass-addition films 33 are arranged is smaller than the acoustic velocity in the central region C. As a result, low-acoustic-velocity regions are configured in a portion of the first outer side region D1 and a portion of the second outer side region D2. The low-acoustic-velocity region is a region in which the acoustic velocity is lower than the acoustic velocity in the central region C.

In the present example embodiment, the central region C and the pair of low-acoustic-velocity regions are arranged in this order from the inner side to the outer side in the second direction. As a result, a transverse mode, which is an unwanted wave, can be reduced or prevented. In addition, also in the present example embodiment, an acoustic wave can be effectively confined in the region in which the acoustic wave is excited, as in the first example embodiment.

It should be noted that at least one mass-addition film 33 only needs to have a wide portion in at least one of the first outer side region D1 and the second outer side region D2. Also in this case, a transverse mode can be prevented.

The mass-addition films that are cyclically positioned in the first direction may be referred to below as first mass-addition films.

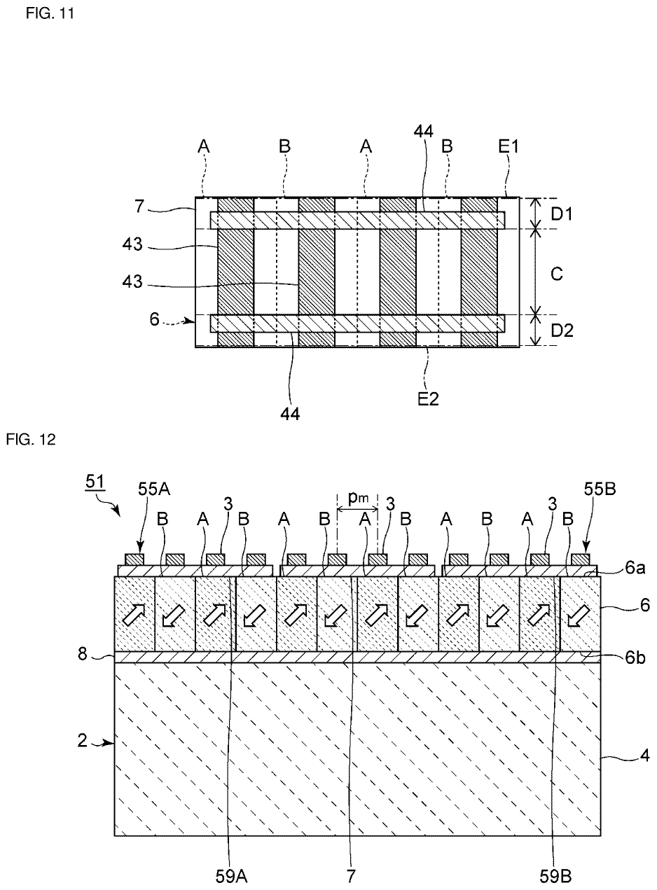

FIG. 11 is a schematic plan view of an acoustic wave device according to a fifth example embodiment.

The present example embodiment differs from the first example embodiment in that a plurality of first mass-addition films 43 and a plurality of second mass-addition films 44 are provided. The acoustic wave device according to the present example embodiment has the same structure as the acoustic wave device 1 according to the first example embodiment with the exception of the points described above.

The plurality of first mass-addition films 43 correspond to the plurality of mass-addition films 3 in the first example embodiment. The plurality of first mass-addition films 43 are configured similarly to the plurality of mass-addition films 3 in the first example embodiment.

In the present example embodiment, the pair of band-shaped second mass-addition films 44 are provided in a portion of the first outer side region D1 and a portion of the second outer side region D2. Specifically, one second mass-addition film 44 of the pair of band-shaped second mass-addition films 44 is continuously provided over the plurality of first mass-addition films 43 and the first electrode 7 in a portion of the first outer side region D1. More specifically, the second mass-addition film 44 is provided from a portion of the central region C located at an edge portion close to the first envelope E1 to a portion located between the edge portion and the first envelope E1 on the first mass-addition films 43 and the first electrode 7. The second mass-addition film 44 does not reach the first envelope E1.

The other second mass-addition film 44 of the pair of band-shaped second mass-addition films 44 is continuously provided over the plurality of first mass-addition films 43 and the first electrode 7 in a portion of the second outer side region D2. More specifically, the second mass-addition film 44 is provided from a portion of the central region C located at the edge portion close to the second envelope E2 to a portion located between the edge portion and the second envelope E2 on the first mass-addition film 43 and the first electrode 7. The second mass-addition film 44 does not reach the second envelope E2.

Since the pair of second mass-addition films 44 is provided, low-acoustic-velocity regions are configured in a portion of the first outer side region D1 and a portion of the second outer side region D2. As a result, a transverse mode can be suppressed. In addition, also in the present example embodiment, as in the first example embodiment, an acoustic wave can be effectively confined in the region in which the acoustic wave is excited.

In the present example embodiment, in a portion in which the first mass-addition film 43 and the second mass-addition film 44 are laminated, the first electrode 7, the first mass-addition film 43, and the second mass-addition film 44 are laminated together in this order. However, in the portion in which the first mass-addition film 43 and the second mass-addition film 44 are laminated, the first electrode 7, the second mass-addition film 44, and the first mass-addition film 43 may also be laminated together in this order.

It should be noted that the plurality of second mass-addition films 44 may be provided in a portion of the first outer side region D1 so as to be arranged in the first direction. In this case, for example, one second mass-addition film 44 may also be laminated on only one first mass-addition film 43. Alternatively, one second mass-addition film 44 laminated on one first mass-addition film 43 may reach the outer side of the first mass-addition film 43 in the first direction. Similarly, the plurality of second mass-addition films 44 may be provided also in a portion of the second outer side region D2 so as to be arranged in the first direction. Also in this case, a transverse mode can be prevented.

In a structure in which the first mass-addition film 43 and the second mass-addition film 44 are provided, at least one second mass-addition films 44 only needs to be provided. Specifically, at least one second mass-addition film 44 only needs to be laminated with at least one first mass-addition film 43 in at least one of the first outer side region D1 and the second outer side region D2. Also in this case, a transverse mode can be prevented.

In an example embodiment of the present invention, the low-acoustic-velocity regions may be configured in both the structure in which the first mass-addition films have wide portions and the structure in which the second mass-addition films are provided.

FIG. 12 is a schematic elevational cross-sectional view of an acoustic wave device according to a sixth example embodiment.

The present example embodiment differs from the first example embodiment in that the pair of reflectors is configured in the cyclic polarization reversal region. The pair of reflectors is specifically a reflector 55A and a reflector 55B. The acoustic wave device 51 according to the present example embodiment has the same structure as the acoustic wave device 1 according to the first example embodiment with the exception of the points described above.

The reflector 55A is configured by a third electrode 59A being provided instead of the first electrode 7. Specifically, the third electrode 59A faces the second electrode 8 with the piezoelectric layer 6 therebetween. The plurality of mass-addition films 3 are provided on the third electrode 59A. The plurality of mass-addition films 3 are cyclically positioned in the first direction on the third electrode 59A. More specifically, each of the mass-addition films 3 provided on the third electrode 59A overlaps one of the first regions A or one of the second regions B in plan view. Similarly, the reflector 55B is configured by a third electrode 59B being provided instead of the first electrode 7.

The third electrode 59A of the reflector 55A and the third electrode 59B of the reflector 55B face each other in the first direction with the first electrode 7 therebetween. The third electrode 59A and the third electrode 59B are not electrically connected to the first electrode 7.

Specifically, on one of the first region A and the second region B that are adjacent to each other, the edge portion of the first electrode 7 close to the third electrode 59A is located. On the other of the first region A and the second region B that are adjacent to each other, the edge portion of the third electrode 59A close to the first electrode 7 is located. Similarly, on one of the first region A and the second region B that are adjacent to each other, the edge portion of the first electrode 7 close to the third electrode 59B is located. On the other of the first region A and the second region B that are adjacent to each other, the edge portion of the third electrode 59B close to the first electrode 7 is located.

In the present example embodiment, the plurality of mass-addition films 3 are cyclically positioned in the first direction over the first electrode 7 and the pair of third electrodes. Specifically, a center-to-center distance pₘ between the adjacent mass-addition films 3 on the first electrode 7, the center-to-center distance pₘ on the third electrode 59A, and the center-to-center distance pₘ on the third electrode 59B are the same as each other. The center-to-center distance pₘ between the mass-addition film 3 closest to the third electrode 59A on the first electrode 7 and the mass-addition film 3 closest to the first electrode 7 on the third electrode 59A is the same as the center-to-center distance pₘ between the adjacent mass-addition films 3 on the first electrode 7. The center-to-center distance pₘ between the mass-addition film 3 closest to the third electrode 59B on the first electrode 7 and the mass-addition film 3 closest to the first electrode 7 on the third electrode 59B is also the same as the center-to-center distance pₘ between the adjacent mass-addition films 3 on the first electrode 7.

The materials of the third electrode 59A and the third electrode 59B may be the same as the materials exemplified above as the materials of the first electrode 7 and the second electrode 8.

An acoustic wave is not excited in the portion in which the reflector 55A and the reflector 55B are configured. However, the reflector 55A and the reflector 55B can reflect an acoustic wave in the acoustic wave propagation direction. As a result, an acoustic wave can be more effectively confined in the region in which the acoustic wave is excited.

As described above, the center-to-center distance between the first region A and the second region B that are adjacent to each other is pᵣ. When the thickness of the piezoelectric layer 6 is d, preferably d/pᵣ≤1 holds, more preferably d/pᵣ≤about 0.5 is satisfied, for example. When the thickness d of the piezoelectric layer 6 is small as described above, the reflection coefficient for reflecting an acoustic wave in the acoustic wave propagation direction is likely to be small. On the other hand, a pair of reflectors is provided in the present example embodiment. As a result, an acoustic wave can be reflected with greater certainty to the region in which the acoustic wave is excited. Accordingly, when the thickness d falls within the range described above, a structure including a pair of reflectors is particularly preferable.

However, in an example embodiment of the present invention, the mass-addition films 3 are cyclically positioned in the first direction. As a result, when the thickness d of the piezoelectric layer 6 is large enough, the reflection coefficient at the boundary between the first region A and the second region B can be sufficiently increased. Accordingly, even when the reflectors are not provided, an acoustic wave can be effectively confined in the region in which the acoustic wave is excited.

The structure in which the pair of reflectors is provided is also applicable to the structure of the present invention excluding the present example embodiment.

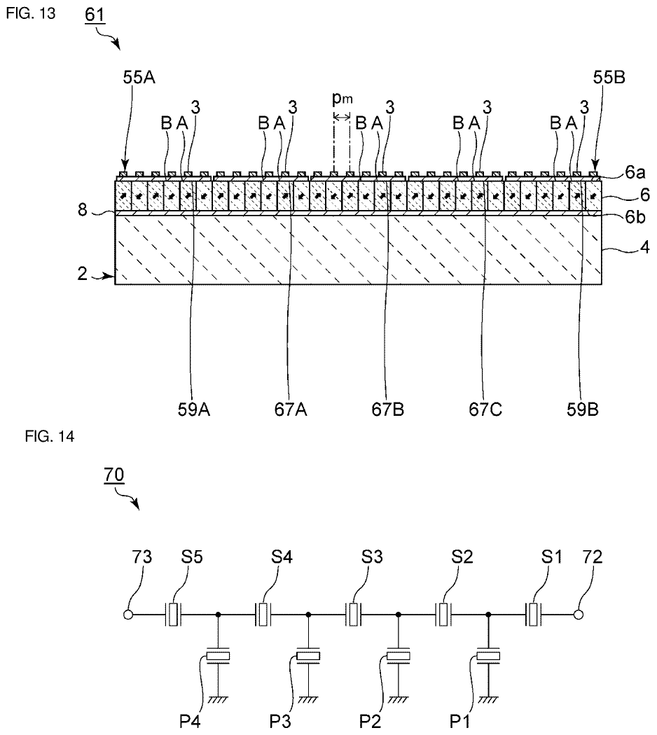

FIG. 13 is a schematic elevational cross-sectional view of an acoustic wave device according to a seventh example embodiment.

The present example embodiment differs from the sixth example embodiment in that the plurality of first electrodes are provided. The plurality of first electrodes are specifically a first electrode 67A, a first electrode 67B, and a first electrode 67C. The acoustic wave device 61 according to the present example embodiment has the same structure as the acoustic wave device 51 according to the sixth example embodiment with the exception of the points described above.

In the first direction, the third electrode 59A of the reflector 55A, the first electrode 67A, the first electrode 67B, the first electrode 67C, and the third electrode 59B of the reflector 55B are disposed in this order. The plurality of first electrodes and the pair of third electrodes face the second electrode 8 with the piezoelectric layer 6 therebetween.

The adjacent first electrodes to each other are not electrically connected to each other. Specifically, the edge portion of the first electrode 67A close to the first electrode 67B is located on one of the first region A and the second region B that are adjacent to each other. The edge portion of the first electrode 67B close to the first electrode 67A is located on the other of the first region A and the second region B that are adjacent to each other. Similarly, the edge portion of the first electrode 67B close to the first electrode 67C is located on one of the first region A and the second region B that are adjacent to each other. The edge portion of the first electrode 67C close to the first electrode 67B is located on the other of the first region A and the second region B that are adjacent to each other.

In the present example embodiment, the first electrode 67A is connected to an output potential. The first electrode 67B is connected to an input potential. The first electrode 67C is connected to the output potential. The second electrode 8 is connected to a reference potential. However, the present invention is not limited to this example. For example, the first electrode 67A and the first electrode 67C may be connected to the input potential, and the first electrode 67B may be connected to the output potential.

In the present example embodiment, the plurality of mass-addition films 3 are cyclically positioned in the first direction over the plurality of first electrodes and the pair of third electrodes. The center-to-center distance pₘ between the adjacent mass-addition films 3 is the same on the plurality of first electrodes.

In the region in which the plurality of first electrodes and the second electrode 8 face each other, an acoustic wave is excited. Also in the present example embodiment, as in the sixth example embodiment, an acoustic wave can be more effectively confined in the region in which the acoustic wave is excited.

In addition, the acoustic wave device 61 corresponds to a resonator in which longitudinal coupling has been formed. Accordingly, when the acoustic wave device 61 is used in a filter device, the size of the filter device can be reduced.

In the present example embodiment, the structure on each of the first electrodes is the same as that in the sixth example embodiment and that in the first example embodiment. However, the structure on each of the first electrodes may be same as, for example, the structures in modifications of the first example embodiment, the structure in the second example embodiment, the structures in the modifications of the second example embodiment, and the structures in the third to fifth example embodiments.

The acoustic wave device 61 includes three first electrodes. It should be noted that the number of first electrodes is not limited to this number. For example, the number of first electrode may be five or seven.

As described above, the acoustic wave devices according to example embodiments of the present invention can be used in, for example, filter devices. This example will be described below.

FIG. 14 is a circuit diagram of a filter device according to an eighth example embodiment.

A filter device 70 includes a first signal terminal 72, a second signal terminal 73, and a plurality of resonators. The filter device 70 is a ladder filter. Accordingly, the plurality of resonators of the filter device 70 include a plurality of series arm resonators and a plurality of parallel arm resonators. In the present example embodiment, all the series arm resonators and all the parallel arm resonators are acoustic wave resonators. In addition, all the acoustic wave resonators are the acoustic wave devices according to example embodiments of the present invention. However, at least one acoustic wave resonator of the series arm resonators and the parallel arm resonators of the filter device 70 only needs to be the acoustic wave devices according to example embodiments of the present invention that has the structure in any one of, for example, the first to sixth example embodiments or modifications thereof.

The first signal terminal 72 and the second signal terminal 73 may be configured as, for example, electrode pads or wiring lines. In the present example embodiment, the second signal terminal 73 is an antenna terminal. The antenna terminal is connected to an antenna.

The plurality of series arm resonators of the filter device 70 are, specifically, a series arm resonator S1, a series arm resonator S2, a series arm resonator S3, a series arm resonator S4, and a series arm resonator S5. The plurality of parallel arm resonators are, specifically, a parallel arm resonator P1, a parallel arm resonator P2, a parallel arm resonator P3, and a parallel arm resonator P4.

The series arm resonator S1, the series arm resonator S2, the series arm resonator S3, the series arm resonator S4, and the series arm resonator S5 are connected in series to each other between the first signal terminal 72 and the second signal terminal 73. The parallel arm resonator P1 is connected to a portion between the ground potential and a connection point between the series arm resonator S1 and the series arm resonator S2. The parallel arm resonator P2 is connected to a portion between the ground potential and a connection point between the series arm resonator S2 and the series arm resonator S3. The parallel arm resonator P3 is connected to a portion between the ground potential and a connection point between the series arm resonator S3 and the series arm resonator S4. The parallel arm resonator P4 is connected to a portion between the ground potential and a connection point between the series arm resonator S4 and the series arm resonator S5.

However, the circuit structure of the filter device 70 is not limited to the structure described above. When the filter device 70 according to an example embodiment of the present invention is a ladder filter, the filter device 70 only needs to include at least one series arm resonator and at least one parallel arm resonator.

Alternatively, the filter device 70 may include, for example, a resonator in which longitudinal coupling has been formed. In this case, the filter device 70 may include, for example, the acoustic wave device 61 according to the seventh example embodiment. When the resonator in which longitudinal coupling has been included is an acoustic wave device according to an example embodiment of the present invention, other resonators do not need to be the acoustic wave devices according to example embodiments of the present invention.

The filter device 70 according to the present example embodiment includes the acoustic wave device according to the present invention as a resonator. Therefore, in the resonator of the filter device 70, an acoustic wave can be effectively confined in the region in which the acoustic wave is excited. Accordingly, the filter characteristics of the filter device 70 can be enhanced with greater certainty.

The filter device 70 preferably includes the plurality of acoustic wave devices according to an example embodiment of the present invention. In addition, the plurality of acoustic wave devices preferably include an acoustic wave device in which a center-to-center distance Pᵣ between the first region A and the second region B that are adjacent to each other differs from the center-to-center distance Pᵣ of another acoustic wave device. In this case, the frequencies of the plurality of acoustic wave devices can be easily differentiated.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface that face away from each other;
a first electrode provided on the first main surface of the piezoelectric layer; and
a second electrode, provided on the second main surface of the piezoelectric layer, that faces the first electrode with the piezoelectric layer therebetween; wherein
the piezoelectric layer includes a first region and a second region in which a polarization direction is reversed from a polarization direction in the first region, and the first region and the second region are cyclically arranged in a direction orthogonal to a thickness direction of the piezoelectric layer;
the acoustic wave device further comprising:
a plurality of mass-addition films provided on the first electrode and cyclically positioned in a direction in which the first region and the second region are arranged.

2. The acoustic wave device according to claim 1, further comprising:
at least one connector connected to at least two of the plurality of the mass-addition films.

3. The acoustic wave device according to claim 1, further comprising:
a dielectric film provided on the first electrode so as to cover the plurality of mass-addition films.

4. The acoustic wave device according to claim 1, wherein each of the plurality of mass-addition films overlaps one of the first regions or one of the second regions in plan view, respectively.

5. The acoustic wave device according to claim 1, wherein the plurality of mass-addition films do not overlap a portion of the first region or the second region in plan view.

6. The acoustic wave device according to claim 1, wherein d/pᵣ≤about 0.5 is satisfied where d is a thickness of the piezoelectric layer, and pᵣ is a center-to-center distance between the first region and the second region that are adjacent to each other.

7. The acoustic wave device according to claim 1, wherein the plurality of mass-addition films include a dielectric material.

8. The acoustic wave device according to claim 1, wherein the plurality of mass-addition films include a metal.

9. The acoustic wave device according to claim 8, wherein the plurality of mass-addition films includes at least one of platinum and molybdenum.

10. The acoustic wave device according to claim 1, further comprising:
a support substrate;
the piezoelectric layer is provided on the support substrate.

11. The acoustic wave device according to claim 10, wherein the support substrate includes silicon.

12. A filter device comprising:
a plurality of resonators; wherein
two or more of the plurality of resonators are each defined by the acoustic wave device according to claim 1; and
the acoustic wave device defining one of the two or more of the plurality of resonators has a center-to-center distance between the first region and the second region adjacent to each other that differs from a center-to-center distance of the acoustic wave device defining another one of the two or more of the plurality of resonators.

13. The filter device according to claim 12, further comprising:
at least one connector connected to at least two of the plurality of the mass-addition films.

14. The filter device according to claim 12, further comprising:
a dielectric film provided on the first electrode so as to cover the plurality of mass-addition films.

15. The filter device according to claim 12, wherein each of the plurality of mass-addition films overlaps one of the first regions or one of the second regions in plan view, respectively.

16. The filter device according to claim 12, wherein the plurality of mass-addition films do not overlap a portion of the first region or the second region in plan view.

17. The filter device according to claim 12, wherein d/pᵣ≤about 0.5 is satisfied where d is a thickness of the piezoelectric layer, and pᵣ is a center-to-center distance between the first region and the second region that are adjacent to each other.

18. The filter device according to claim 12, wherein the plurality of mass-addition films include a dielectric material.

19. The filter device according to claim 12, wherein the plurality of mass-addition films include a metal.

20. The filter device according to claim 19, wherein the plurality of mass-addition films includes at least one of platinum and molybdenum.

21. The filter device according to claim 12, further comprising:
a support substrate;
the piezoelectric layer is provided on the support substrate.

22. The filter device according to claim 12, wherein the support substrate includes silicon.
